(19) United States
(12) Patent Application Publication
(10) Pub. No.: US 2025/0083992 A1
(43) Pub. Date: Mar. 13, 2025

(54) GLASS, ESPECIALLY AS A COVER

(71) Applicants: Schott AG, Mainz (DE); SCHOTT Technical Glass Solutions GmbH, Jena (DE)

(72) Inventors: Sebastian Leukel, Mainz (DE); Patrick Wilde, Mainz (DE); Eric Oberländer, Jena (DE)

(73) Assignees: Schott AG, Mainz (DE); SCHOTT Technical Glass Solutions GmbH, Jena (DE)

(21) Appl. No.: 18/825,608

(22) Filed: Sep. 5, 2024

(30) Foreign Application Priority Data
Sep. 7, 2023 (DE) 10 2023 124 136.2

(51) Int. Cl. C03C 3/11; C03C 4/02; C03C 21/00; H05K 5/03

(52) U.S. Cl. CPC C03C 3/11; C03C 4/02; C03C 21/002; C03C 2204/00; H05K 5/03

(57) ABSTRACT

A chemically temperable or chemically tempered glass includes SiO₂, Al₂O₃, Li₂O and B₂O₃ as constituents. The following applies for the constituents (in mol % based on oxide): 0.8<Li₂O/(Li₂O+K₂O+Na₂O)≤1 and 0.1<B₂O₃≤8.5.

### CROSS-REFERENCE TO RELATED APPLICATIONS

This application claims priority to German Patent Application No. 10 2023 124 136.2 filed on Sep. 7, 2023, which is incorporated in its entirety herein by reference.

### BACKGROUND OF THE INVENTION

### 1. Field of the Invention

The present invention relates to a chemically temperable or chemically tempered glass, to a process for the production thereof, to a cover made of such a glass and the use thereof and to a digital display device comprising such a cover.

### 2. Description of the Related Art

The use of glass or glass ceramics as covers for electronic components and displays, in particular for smartphones, has long been known. These glass-based materials are optionally chemically tempered to increase their mechanical strength.

Glasses made of the Li₂O—Al₂O₃—SiO₂ system, so-called LAS glasses, have proven particularly suitable here. They comprise SiO₂ and Li₂O and Al₂O₃ as primary components. LAS glasses include the subgroup of boron-containing LAS glasses, also known as LABS glasses.

Compared to AS glasses, i.e. Li-free glasses, especially having regard to their use as cover materials, LABS glasses have the advantage that they are very readily chemically temperable through ion exchange of Li ions for Na ions or through combined ion exchange, namely Li ions for Na ions and Na ions for K ions, and thus have a high mechanical strength both against so-called “sharp impact stresses”, i.e. against the influence of rough surfaces and sharp objects, and against the influence of blunt or smooth surfaces, so-called “blunt impact stresses”. LABS glasses are preferred compared to LAS glasses since the addition of B₂O₃ results in stronger bonding of the glass network and further improved mechanical properties, such as scratch resistance.

Such glasses are known from the prior art.

Thus, U.S. Patent Application Publication No. 2017/197869 A describes LABS glasses which, according to the examples, have a relatively high coefficient of expansion and have a low Li₂O proportion in the total content of alkali metal oxides.

U.S. Patent Application Publication No. 2018/186685 A also describes LABS and LAS glasses. Especially the LABS glasses have a low Li₂O proportion in the total content of alkali metal oxides.

U.S. Patent Application Publication No. 2018/127302 A describes LABS glasses having rather low Li₂O contents based on the total alkali metal oxide content and/or high boron contents.

U.S. Patent Application Publication No. 2020/317558 A describes AS, i.e. Li-free, glasses or LA (B) S glasses, wherein these have rather low Li contents and/or lack B₂O₃.

German Patent Application No. 10 2019 121 146 A describes LAS glasses having a minimum content of the nucleating agents ZrO₂, SnO₂ and TiO₂.

German Patent Application No. 10 2019 121 143 A describes LAS glasses having rather high contents of alkali metal oxide, especially Na₂O.

What the different glasses of the prior art having the abovementioned good product properties have in common is that they are difficult to process. This concerns the behaviour not only of the glass melt in the refining zone but also of the glass during shaping and cooling, as well as its susceptibility to crystallization.

What is needed in the art is a way to provide a chemically temperable or tempered glass, especially for use as cover glass, which, on account of its viscosity properties, is easily fusible, refinable and hot-formable and is economic to produce. The glass shall naturally also exhibit the product properties necessary for its intended use in the tempered state.

What are also needed are a process for producing such a glass and to a cover made of such a glass and the use thereof and to a digital display device comprising such a cover.

### SUMMARY OF THE INVENTION

In some embodiments provided according to the invention, a chemically temperable or chemically tempered glass includes SiO₂, Al₂O₃, Li₂O and B₂O₃ as constituents. The following applies for the constituents (in mol % based on oxide): 0.8<Li₂O/(Li₂O+K₂O+Na₂O)≤1 and 0.1<B₂O_{3≤8.5.}

In some embodiments provided according to the invention, a process for producing a tempered glass is provided. The glass includes SiO2, Al2O3, Li2O and B2O3 as constituents. The following applies for the constituents (in mol % based on oxide): 0.8<Li2O/(Li2O+K2O+Na2O)≤1 and 0.1<B2O3≤8.5. The method includes: producing the glass by a melting process, a refining of a glass melt produced during the melting process, and a subsequent hot forming; and performing at least one ion exchange in an exchange bath having a composition of 100% by weight to 0% by weight of KNO3 and 0% by weight to 100% by weight of NaNO3 and 0% by weight to 5% by weight of LiNO3 at a temperature of the exchange bath between 370° C. and 500° C. and a duration between 1 hour and 50 hours.

In some embodiments provided according to the invention, a cover includes a tempered glass having a thickness of 0.3 mm to 1 mm. The glass includes SiO2, Al2O3, Li2O and B₂O₃ as constituents. The following applies for the constituents (in mol % based on oxide): 0.8<Li2O/(Li2O+K2O+Na2O)≤1 and 0.1<B2O3≤8.5.

### DETAILED DESCRIPTION OF THE INVENTION

The chemically temperable or chemically tempered glass provided according to the invention comprises the constituents SiO₂, Al₂O₃, Li₂O and B₂O₃ and optionally Na₂O and optionally K₂O. The following applies for the B₂O₃ content (in mol % based on oxide): 0.1<B₂O_{3≤8.5}; optionally 0.1<B₂O_{3<8.5.}

The recited minimum content of B₂O₃ is necessary for a low upper devitrification limit. The upper devitrification limit is the temperature at which the glass is free from crystals after heating from room temperature and holding for one hour. LABS glasses generally crystallize upon heating in a temperature range above the glass transition temperature Tg. If the temperature is further increased, the crystals redissolve. Since the dissolution may proceed slowly due to the viscosity of the glass, the temperature is held for 1 h. The upper devitrification limit is a measure of the susceptibility of a glass to crystallization. If said limit is low, this advantageously means that the glass is less prone to crystallization (the crystals are rather “unstable” and dissolve even at low temperatures) and is therefore also more readily producible. Contents higher than the recited contents of B₂O₃ can result in demixing and are disadvantageous for ion diffusion, especially of K ions.

The following applies for the alkali metal oxides Li₂O, Na₂O and K₂O (all contents in mol %): 0.8<Li₂O/(Li₂O+K₂O+Na₂O)≤1. This condition can be met by the presence of all three recited alkali metal oxides or of Li₂O together with K₂O or with Na₂O or else by the sole presence of Li₂O (Li₂O/(Li₂O+K₂O+Na₂O)=1). A ratio of Li₂O/(Li₂O+K₂O+Na₂O)<1 may be preferred.

The chemically temperable or chemically tempered glass provided according to the invention has an upper devitrification temperature OEG which is less than 10 K above the processing temperature VA, optionally below it. This makes it possible to avoid uncontrolled crystallization of undesired crystal phases, for example spodumene, keatite, forsterite, baddeleyite, gahnite, during the production process, in particular during the hot forming.

The processing temperature VA, i.e. the temperature at a viscosity of 10⁴ dPas, may by preference be less than 1300° C., optionally less than 1260° C., particularly optionally less than 1220° C. This facilitates shaping and especially makes it possible to establish a low homogeneous glass thickness, especially in a float bath.

The glass has a temperature at a viscosity of 10² dPas, known as T2, of at most 1800° C., optionally of less than 1750° C., optionally of less than 1720° C. As a result, the glass is readily refinable and, as a product, exhibits good optical quality without gas inclusions, i.e. without scatter.

The glass has a coefficient of thermal expansion CTE20-300 of less than 5.4 ppm/K. This allows stress-free cooling after the hot-forming process. The glass optionally has a coefficient of thermal expansion CTE20-300 of more than 3.8 ppm/K.

The glass provided according to the invention having the specified properties may be realized via a LABS glass having a composition comprising the specified features 0.1<B₂O₃≤ 8.5 and 0.8<Li₂O/(Li₂O+K₂O+Na₂O)≤1.

The glass optionally exhibits good chemical resistances both in the untempered state and in the tempered state, namely:
a hydrolytic resistance H according to DIN 52296: Glass and glass ceramics: Hydrolytic resistance of the surface of glass and glass ceramic plates at 98° C.,
method of test and classification (modification: determination of additional cations with ICP) (1989-12);
an alkali resistance L according to DIN ISO 695: Glass: Resistance to attack by a boiling aqueous solution of mixed alkali, method of test and classification (1994 02);
and an acid resistance S according to DIN 12116: Testing of glass-Resistance to attack by a boiling aqueous solution of hydrochloric acid, method of test and classification (2001 03);
of class 3 or better in each case.

In the context of the present disclosure the constituents of the glass are reported in mol % based on oxide.

In some embodiments, the proportions of these constituents in mol % based on oxide are:
SiO₂ 62-72, optionally 65-70,
and/or
Al₂O₃ 7-14, optionally 8-12,
and/or
B₂O₃ 0.1-8.5, optionally <8.5 or ≤8, optionally 4-7, optionally ≥5, optionally>5.5,
and/or
Li₂O 5-12, optionally 7-10,
and/or
Na₂O 0-2, optionally 0-1, optionally ≥0.1 and/or <1, optionally ≥0.3 and/or <0.8, and/or
K₂O 0-2, optionally 0-1.

The presence of SiO₂, optionally at a minimum content of 62 mol % or even 65 mol %, is necessary for the formation of a stable glass network, which increases mechanical and chemical resistance. SiO₂ increases the viscosity of the melt. Excessive levels should be avoided to allow fusibility and to have a sufficiently low viscosity for ascending of bubbles during refining. The maximum content thereof is therefore optionally limited to 72 mol %, particularly optionally to 70 mol %.

The presence of Al₂O₃, optionally at a minimum content of 7 mol % or even 8 mol %, is necessary to allow rapid alkali diffusion in the glass and high compressive stresses (CS30 and CS50 values). At excessive Al₂O₃ contents the crystallization propensity of the glass increases markedly. The maximum content thereof is therefore optionally limited to 14 mol %, particularly optionally to 12 mol %.

The presence of B₂O₃, optionally at a minimum content of 4 mol % or 5 mol % or more than 5 mol % or even of 5.5 mol % or more than 5.5 mol %, has a positive effect on fusibility. Contents above the exemplary upper limit of 8.5 mol % can already lead to a slight decrease in chemical resistance and CS30 and CS50 values. The B₂O₃ content is therefore optionally limited to less than 8.5 mol % or to at most 8 mol %, optionally to at most 7 mol %.

The presence of Li₂O, optionally at a minimum content of 5 mol %, optionally at a minimum content of 7 mol %, allows chemical tempering of the glass in a sodium-containing salt bath. The content thereof is optionally limited to 12 mol %, optionally to 10 mol %, since otherwise the crystallization propensity increases markedly, especially with precipitation of Li₂O-containing (and Al₂O₃-containing) crystal phases such as for example spodumene or keatite.

If Na₂O is present, optionally at a content of at least 0.1 mol %, optionally at at least 0.3 mol %, this may be advantageous for the fusibility and inhibits crystallization. Due to the adverse effect on compressive stresses (CS30 and CS50 values) and the increase in the thermal coefficient of expansion, its maximum content is optionally limited to 2 mol %, optionally to 1 mol %, and optionally to less than 1 mol %.

If K₂O is present this has a positive effect on fusibility. K₂O additionally increases K diffusion in the glass and allows for a deeper tempering (K-DoL) in the last tempering step in multi-stage tempering. The K₂O content is optionally limited to 1 mol % since excessively high K₂O contents have an adverse effect on the K-induced tempering (KCS).

In some embodiments, the glass may comprise the following constituents (in mol % based on oxide):
MgO 0-5, optionally 0.5-3,
and/or
CaO 0-8, optionally 1-6,
and/or
SrO 0-5, optionally 0-1,
and/or
BaO 0-2,
and/or
ZnO 0-5, optionally 0-1,
and/or
P₂O₅ 0-5, optionally 0.5-2,
and/or
ZrO₂ 0-5, optionally 0-3.

Alkaline earth metal oxides and/or ZnO may be used to reduce the viscosity of the glass and thus improve manufacturability.

If ZnO is present, the content thereof is optionally limited to 5 mol %, optionally to 1 mol %, since higher contents can result in evaporation during the melting process and thus in corrosion of the refractory material in glass production.

If MgO is present, optionally at a minimum content of 0.5 mol %, this has a positive effect on fusibility. Contents above 5 mol % favor crystallization and are thus optionally avoided. In some embodiments the content is therefore also limited to at most 3 mol %.

If CaO is present, optionally at a minimum content of 1 mol %, this favors the desired low upper devitrification temperature OEG.

If SrO is present the content thereof is optionally limited to 5 mol %, optionally to 1 mol %, since higher contents result in a reduction in alkali metal diffusion in the glass during chemical tempering with the result that very long tempering times become necessary or only low DoCL values are achievable.

If BaO is present the content thereof is optionally limited to 2 mol %. It may be preferable when the glass is substantially free from BaO.

If P₂O₅ is present, optionally with a minimum content of 0.5 mol %, this has a positive effect on alkali metal diffusion in the glass. This is advantageous because the duration of ion exchange can be shortened. The P₂O₅ content should optionally not exceed 5 mol %, optionally 2 mol %, since excessively high contents may lead to corrosion of the refractory material in glass production.

If ZrO₂ is present this has a positive effect on the chemical resistance of the glass. However, high contents of ZrO₂ promote devitrification. The maximum content thereof is thus optionally limited to 5 mol %, optionally to 3 mol %, optionally to 2 mol % or even to only 1 mol %.

The glass may also contain TiO₂ for example. If TiO₂ is present the content thereof is optionally limited to 2 mol %. It may be preferable when the glass is substantially free from TiO₂.

The term “substantially free” is to be understood as meaning that only impurities that are unavoidable in customary and economic methods (for example due to raw materials) are present.

Certain relationships between the components have proven highly advantageous for the glass and its manufacturability and chemical temperability. The composition thereof is thus optionally chosen such that the following applies for the constituents (in mol % based on oxide):
0.9<(Al₂O₃+B₂O₃+ZrO₂)/(R₂O+RO)<1.7;
optionally 1<(Al₂O₃+B₂O₃+ZrO₂)/(R₂O+RO)<1.6;
optionally 1.1<(Al₂O₃+B₂O₃+ZrO₂)/(R₂O+RO)<1.5;
and/or
0.5<Al₂O₃/(R₂O+RO)<1.1;
optionally 0.6<Al₂O₃/(R₂O+RO)<0.9;
optionally 0.7<Al₂O₃/(R₂O+RO)<0.85;
wherein R₂O=Li₂O+K₂O+Na₂O and
RO=MgO+CaO+SrO+BaO+ZnO.

A ratio of 0.5<Al₂O₃/(R₂O+RO)<1.1 is advantageous for glass formation.

If the Al₂O₃/(R₂O+RO) ratio is greater than 1.1, the crystallization propensity to form Al₂O₃-containing crystals increases markedly since there is insufficient R₂O and RO to “dissolve” all of the Al₂O₃ in the glass. At an Al₂O₃/(R₂O+RO) ratio of less than 0.5 an excessive amount of non-bonding bridging oxygens is present and the alkali metal diffusion is reduced since the negative charges are concentrated on individual oxyanions and are no longer delocalized over a whole AlO₄ tetrahedron. This leads to stronger electrostatic bonding of the mobile alkali metal cations to the glass matrix and the chemical temperability suffers.

A ratio of 0.9<(Al₂O₃+B₂O₃+ZrO₂)/(R₂O+RO)<1.7 has a positive effect on the connectivity of the glass network and thus on the mechanical stability. Such a ratio also ensures that boron cations are optionally coordinated trigonally with oxygen and not as tetragonal BO₄ units. Tetragonal BO₄ units have a marked adverse effect on alkali metal diffusion, especially of potassium cations.

In some embodiments the glass may contain 0 to 1 mol % of SnO₂, optionally 0.1 to 0.5 mol % of SnO₂, and/or 0 to 1 mol % of CeO₂ and/or 0 to 1 mol % of Cl, wherein the sum of CeO₂+SnO₂+Cl is optionally at most 2 mol %.

In some embodiments the glass may contain up to 2 mol %, optionally up to 1 mol %, of the customary refining agents such as As₂O₃, Sb₂O₃, SnO₂, CeO₂, halides, optionally chlorides, or sulfur-containing compounds. For reasons of environmental protection and occupational health and especially also when produced in the float process, the glass is optionally substantially free from arsenic and antimony. This also applies to other toxic or environmentally harmful components, for example PbO, TeO₂, CdO.

Especially when it is to be used as a front cover, the glass is also optionally substantially free from coloring components, especially free from coloring rare earths, in particular Nd₂O₃, Er₂O₃, and coloring metal oxides, in particular V₂O₅, CoO, NiO, Cr₂O₃, CuO.

At a thickness of 0.6 mm such a colorless glass optionally has an average transmittance in the range from 365 to 640 nm of at least 85%.

Especially if the glass is to be used as a back cover it optionally contains coloring components, for example at least 0.1 mol % and at most 5 mol % of at least one coloring component, especially optionally selected from the group of CoO, Fe₂O₃, TiO₂, Cr₂O₃ and/or MnO and/or mixtures thereof.

The iron content of the glass, reported as a percentage by weight of Fe₂O₃, should optionally be less than 1000 ppm, particularly optionally less than 500 ppm, to avoid undesired coloring of the material. The iron content of the glass is thus a consequence of unavoidable impurities in the raw materials. The use of low-iron raw materials makes it possible to reduce the amount of iron and thus achieve a better (more neutral) intrinsic color of the glass, though this is generally associated with higher raw material costs.

The glass provided according to the invention is suitable for producing a cover in electronic devices for example, in particular in electronic display devices, in particular in mobile electronic display devices, for example in mobile touch panels and/or mobile digital display devices such as smartphones or smartwatches and generally touch panels.

The cover optionally has a thickness of 0.3 mm to 1 mm, optionally 0.35 mm to 0.7 mm, optionally 0.4 mm to 0.65 mm.

The process for producing a glass comprises the steps of:
producing a silicatic glass by a melting process and
refining the glass melt and
subsequently hot forming.

The hot forming can be carried out, without limiting generality, for example by a drawing process, in particular a float process or a down-draw process, for example an overflow fusion or a drawing nozzle process.

To produce a tempered glass, in particular in embodiments for use as a cover, the above steps are followed by the following step:
performing at least one ion exchange in an exchange bath having a composition of 100% by weight to 0% by weight of KNO3 and 0% by weight to 100% by weight of NaNO3 and 0% by weight to 5% by weight of LiNO3 at a temperature of the exchange bath between 370° C. and 500° C. and a duration between 1 hour and 50 hours.

A further possibility is performing an ion exchange in more than one exchange bath, for example initially performing an ion exchange in an exchange bath having a composition of 50% by weight to 0% by weight of KNO3 and 50% by weight to 100% by weight of NaNO3 and 0% by weight to 5% by weight of LiNO3 at a temperature of the exchange bath between 370° C. and 500° C. and a duration between 1 hour and 20 hours and then performing a further ion exchange in an exchange bath having a composition of 100% by weight to 50% by weight of KNO₃ and 0% by weight to 50% by weight of NaNO3 and 0% by weight to 5% by weight of LiNO₃ at a temperature of the exchange bath between 370° C. and 500° C. and a duration between 1 hour and 20 hours.

Ion exchange in three or more exchange baths is also possible.

The cover made of tempered glass is a high-strength cover.

The high proportion of Li₂O in the total alkali metal content of the LABS glass, expressed by Li₂O/(Li₂O+K₂O+Na₂O)>0.8, makes it possible even at low glass thickness to achieve good stress values in the tempering process, i.e. high stresses CS not only at the surface but also near the surface, namely CS30>100 MPa, and near the depth of the compressive stress zone, namely CS50>80 MPa, and a deep compressive stress zone DoCL, namely DoCL>0.17*t, wherein t is the thickness of the pane.

Here, CS30, reported in MPa, is the compressive stress at a distance of 30 μm from the surface of a main face, CS50, reported in MPa, is the compressive stress at a distance of 50 μm from the surface of the same main face and DoCL, reported in μm similarly to the thickness of the pane, is the depth of the compressive stress zone of the same main face.

The main faces are those of the glass pane that are the largest in terms of their surface area compared to the other faces. In addition to the two main faces a pane optionally comprises four faces joining the two main faces which are referred to as edge faces. In the case of non-rectangular panes the pane may also have fewer edge faces, for example only one edge face.

The tempering process is a chemical tempering which is optionally carried out by immersing the pane in an exchange bath but may also be carried out by application of pastes to the pane.

An exchange bath is to be understood as meaning a salt melt, wherein this salt melt is used in an ion exchange process for a glass or a glass article. In the context of the present disclosure the terms exchange bath and ion-exchange bath are used synonymously.

Exchange baths generally employ technical-purity salts. This means that, despite the use of, for example, only sodium nitrate as the starting material for an exchange bath the exchange bath still comprises certain impurities. The exchange bath is a melt of a salt, that is to say for example of sodium nitrate, or a mixture of salts, for example a mixture of a sodium salt and a potassium salt. The composition of the exchange bath is reported such as to refer to the nominal composition of the exchange bath without taking into account any impurities present. If in the context of the present invention reference is made to a 100% sodium nitrate melt this is accordingly to be understood as meaning that only sodium nitrate was used as raw material. However, the actual sodium nitrate content of the exchange bath may differ therefrom and will indeed generally do so since especially technical grade raw materials comprise a certain proportion of impurities. However, this is generally less than 5% by weight, based on the total weight of the exchange bath, in particular less than 1% by weight.

Similarly, in the case of exchange baths comprising a mixture of different salts it is generally the nominal contents of the salts that is reported without taking into account impurities resulting from technical grade starting materials. An exchange bath comprising 90% by weight of KNO₃ and 10% by weight of NaNO3 may thus likewise comprise a low level of impurities which, however, are a consequence of the raw materials and should generally be less than 5% by weight based on the total weight of the exchange bath, in particular less than 1% by weight.

The composition of the exchange bath also changes in the course of the ion exchange since especially lithium ions migrate out of the glass/the glass article into the exchange bath as a result of ongoing ion exchange. However, such a change in the composition of the exchange bath due to ageing is likewise not taken into account in this case, unless otherwise stated explicitly. On the contrary, in the context of the present disclosure the reported composition of an exchange bath refers to the nominal original composition.

The invention will now be more particularly elucidated by reference to examples.

The compositions of examples of glasses provided according to the invention are reported in Table 1 (all amounts in mol % based on oxide). The compositions of comparative glasses (designations beginning with V) are reported in Table 2 (all amounts in mol % based on oxide).

The materials specified in Tables 1 and 2 were melted and refined using raw materials customary in the glass industry at temperatures from 1550° C. to 1680° C. Melting of the mixture was initially carried out in a Pt/Rh crucible at 1550° C. to 1620° C. The melt was then refined at 1650° C. to 1680° C. and then homogenized by stirring for 30 minutes. After standing at 1550° C. to 1650° C. for 2 h, castings of about 140 mm×100 mm×30 mm in size were cast and annealed at about 500° C. to 650° C. in a lehr and then cooled to room temperature. The cast pieces were used to prepare the test specimens for measuring the properties in the untempered state. The samples for the tempering tests had a thickness of about 0.5 mm.

Tables 1 and 2 report the following properties both for the glasses provided according to the invention and for the comparative glasses:
the coefficient of thermal expansion CTE20-300, determined by dilatometry and specified in ppm/K;
the glass transition temperature Tg determined by dilatometry and reported in ° C.;
the temperature at a viscosity 10² dPas, referred to as T2, reported in ° C. and calculated from the Vogel-Fulcher-Tammann (VFT) equation;
wherein the VFT curve describes the decadic logarithm of the viscosity by means of three parameters A, B and TO as a function of temperature T:

$$lg ( \vert η \vert ) = A + B / ( T - T 0 )$$

wherein VFT parameters (A, B, T0) are determined by fitting the measurement data of viscosity vs. temperature using the VFT function;
the density ρ, reported in g/cm³;
the temperature at a viscosity 10⁴ dPas, referred to as processing temperature VA, reported in ° C. and determined using a stirring viscometer;
the temperature at a viscosity 10³ dPas, referred to as T3, reported in ° C. and determined using a stirring viscometer;
the upper devitrification temperature, referred to as the OEG, reported in ° C. and determined by gradient tempering. Glass grit is placed on a platinum carrier in a gradient furnace and tempered for one hour. The platinum carrier with the glass is then removed. The temperature at the hot end of the gradient, above which the glass is crystal-free, is referred to as the upper devitrification temperature. The glass samples are inspected for crystals using an optical microscope.

The decadic logarithm of the liquidus viscosity, referred to as lg, reported in dPa*s is the viscosity at the upper devitrification temperature and is determined from the VFT parameters A, B, TO and the OEG according to lg (|η|)=A+B/(OEG−T0).

The abbreviation “n.d.” in the table stands for “not determined”.

### Working Examples

TABLE 1

| | Composition [mol %] | | | | | | | | | | | | |
|---|---|---|---|---|---|---|---|---|---|---|---|---|---|
| | 1 | 2 | 3 | 4 | 5 | 6 | 7 | 8 | 9 | 10 | 11 | 12 | 13 |
| SiO₂ | 71.25 | 68.45 | 67.75 | 68.25 | 68.05 | 68.05 | 67.75 | 67.75 | 67.75 | 68.45 | 67.55 | 67.95 | 67.25 |
| Al₂O₃ | 8.50 | 11.00 | 11.00 | 11.00 | 11.00 | 11.00 | 11.00 | 11.00 | 11.50 | 11.00 | 11.40 | 11.00 | 11.40 |
| B₂O₃ | 8.00 | 4.00 | 7.00 | 6.60 | 6.60 | 6.60 | 6.60 | 6.60 | 5.80 | 4.00 | 5.70 | 5.80 | 5.70 |
| Li₂O | 8.00 | 8.00 | 8.00 | 8.20 | 8.20 | 8.20 | 8.20 | 8.20 | 8.20 | 8.00 | 8.20 | 8.70 | 8.20 |
| Na₂O | 0.70 | 0.70 | 0.70 | 0.70 | 0.70 | 0.70 | 0.70 | 0.40 | 0.70 | 0.70 | 0.70 | 0.70 | 0.70 |
| K₂O | 0.20 | 0.20 | 0.20 | 0.20 | 0.20 | 0.50 | 0.50 | 0.50 | 0.50 | 0.50 | 0.50 | 0.50 | 0.50 |
| MgO | 1.00 | 1.50 | 1.00 | 1.00 | 0.50 | 0.50 | 0.50 | 0.50 | 0.70 | 1.00 | 1.10 | 0.50 | 1.40 |
| CaO | 0.50 | 4.30 | 2.50 | 2.50 | 3.20 | 2.90 | 2.90 | 3.20 | 3.00 | 4.50 | 3.00 | 3.00 | 3.00 |
| SrO | | | | | | | | | | | | | |
| BaO | | | | | | | | | | | | | |
| ZnO | 0.11 | 0.11 | 0.11 | 0.11 | 0.11 | 0.11 | 0.11 | 0.11 | 0.11 | 0.11 | 0.11 | 0.11 | 0.11 |
| P₂O₅ | 0.50 | 0.50 | 0.50 | 0.50 | 0.50 | 0.50 | 0.50 | 0.50 | 0.50 | 0.50 | 0.50 | 0.50 | 0.50 |
| Fe₂O₃ | | | | | | | | | | | | | |
| TiO₂ | | | | | | | | | | | | | |
| ZrO₂ | 0.40 | 0.40 | 0.40 | 0.10 | 0.10 | 0.10 | 0.40 | 0.40 | 0.40 | 0.40 | 0.40 | 0.40 | 0.40 |
| CeO₂ | 0.15 | 0.15 | 0.15 | 0.15 | 0.15 | 0.15 | 0.15 | 0.15 | 0.15 | 0.15 | 0.15 | 0.15 | 0.15 |
| SnO₂ | 0.14 | 0.14 | 0.14 | 0.14 | 0.14 | 0.14 | 0.14 | 0.14 | 0.14 | 0.14 | 0.14 | 0.14 | 0.14 |
| SO₃ | | | | | | | | | | | | | |
| F | | | | | | | | | | | | | |
| Cl | 0.55 | 0.55 | 0.55 | 0.55 | 0.55 | 0.55 | 0.55 | 0.55 | 0.55 | 0.55 | 0.55 | 0.55 | 0.55 |

| Properties | 1 | 2 | 3 | 4 | 5 | 6 | 7 |
|---|---|---|---|---|---|---|---|
| CTE20-300 | 4.33 | 4.76 | 4.55 | 4.61 | 4.68 | 4.76 | 4.76 |
| [ppm/K] | | | | | | | |
| Tg [° C.] | 557 | 596 | 588 | 580 | 586 | 577 | 585 |
| T2 (from | 1799 | 1693 | 1680 | 1702 | 1702 | 1705 | 1687 |
| VFT) [° C.] | | | | | | | |
| ρ [g/cm³] | 2.3134 | 2.4056 | 2.3593 | 2.3549 | 2.3613 | 2.3581 | 2.367 |
| VA [° C.] | 1242 | 1219 | 1214 | 1227 | 1220 | 1215 | 1212 |
| T3 [° C.] | 1465 | 1412 | 1405 | 1422 | 1417 | 1414 | 1407 |
| VFT A | −1.994 | −2.373 | −2.555 | −2.584 | −2.467 | −2.325 | −2.532 |
| VFT B | 6670.3 | 6597.9 | 6962.8 | 7171.5 | 6958.7 | 6700.9 | 7017.7 |
| VFT T0 | 129.0 | 184.0 | 151.5 | 137.4 | 144.5 | 155.3 | 138.2 |
| OEG [° C.] | 1235 | 1225 | 1205 | 1230 | 1185 | 1185 | 1195 |
| lg (Liquidus | 4.04 | 3.97 | 4.05 | 3.98 | 4.22 | 4.18 | 4.11 |
| Viscosity) | | | | | | | |
| [dPa*s] | | | | | | | |

| Properties | 8 | 9 | 10 | 11 | 12 | 13 |
|---|---|---|---|---|---|---|
| CTE20-300 | 4.67 | 4.77 | 4.9 | 4.78 | 4.91 | n.d. |
| [ppm/K] | | | | | | |
| Tg [° C.] | 586 | 593 | 589 | 595 | 581 | n.d. |
| T2 (from | 1682 | 1687 | 1688 | 1678 | 1689 | n.d. |
| VFT) [° C.] | | | | | | |
| ρ [g/cm³] | 2.3684 | 2.375 | 2.4053 | 2.38 | 2.3758 | n.d. |
| VA [° C.] | 1212 | 1223 | 1215 | 1216 | 1208 | n.d. |
| T3 [° C.] | 1404 | 1413 | 1408 | 1406 | 1404 | n.d. |
| VFT A | −2.494 | −2.590 | −2.399 | −2.598 | −2.382 | n.d. |
| VFT B | 6849.5 | 7024.7 | 6654.5 | 7006.2 | 6728.1 | n.d. |
| VFT T0 | 157.6 | 156.7 | 175.2 | 154.0 | 153.8 | n.d. |
| OEG [° C.] | 1195 | 1205 | 1185 | 1190 | 1210 | n.d. |
| lg (Liquidus | 4.11 | 4.11 | 4.19 | 4.16 | 3.99 | n.d. |
| Viscosity) | | | | | | |
| [dPa*s] | | | | | | |

### Comparative Examples

TABLE 2

| | Composition [mol %] | | | | | | | | | | | | | | |
|---|---|---|---|---|---|---|---|---|---|---|---|---|---|---|---|
| | V1 | V2 | V3 | V4 | V5 | V6 | V7 | V8 | V9 | V10 | V11 | V12 | V13 | V14 | V15 |
| SiO₂ | 68.96 | 69.51 | 66.51 | 66.09 | 68.09 | 67.09 | 63.22 | 68.88 | 67.68 | 70.98 | 68.65 | 68.65 | 68.45 | 68.95 | 73.40 |
| Al₂O₃ | 10.44 | 10.00 | 13.00 | 13.00 | 11.00 | 11.00 | 15.10 | 11.00 | 11.50 | 8.50 | 11.00 | 11.00 | 11.00 | 11.00 | 11.50 |
| B₂O₃ | 3.60 | 3.80 | 3.80 | 3.80 | 3.80 | 3.80 | 4.00 | 4.00 | 3.00 | 4.00 | 4.60 | 4.60 | 4.60 | 3.60 | |
| Li₂O | 8.45 | 8.70 | 8.70 | 8.70 | 8.70 | 8.70 | 9.70 | 8.00 | 8.00 | 8.00 | 8.20 | 8.20 | 8.20 | 8.20 | 8.50 |
| Na₂O | 2.35 | 0.50 | 0.50 | 0.70 | 0.70 | 0.70 | 0.70 | 0.70 | 0.70 | 0.70 | 1.20 | 0.70 | 0.70 | 0.70 | 2.00 |
| K₂O | 0.20 | 0.20 | 0.20 | 0.20 | 0.20 | 0.20 | 0.20 | 0.20 | 0.20 | 0.20 | 0.20 | 0.50 | 0.50 | 0.50 | 0.10 |
| MgO | 2.00 | 3.70 | 3.70 | 2.50 | 2.50 | 2.50 | 2.00 | 2.50 | 6.00 | 5.50 | 1.30 | 1.30 | 0.50 | 0.50 | 0.80 |
| CaO | 2.80 | 2.50 | 2.50 | 4.30 | 4.30 | 4.30 | 4.50 | 3.30 | 1.50 | 0.50 | 3.30 | 3.50 | 4.50 | 5.00 | 2.00 |
| SrO | 0.24 | | | | | | | | | | | | | | 0.80 |
| BaO | | | | | | | | | | | | | | | |
| ZnO | 0.11 | 0.10 | 0.10 | 0.11 | 0.11 | 0.11 | 0.11 | 0.11 | 0.11 | 0.11 | 0.11 | 0.11 | 0.11 | 0.11 | 0.15 |
| P₂O₅ | 0.26 | 0.25 | 0.25 | 0.27 | 0.27 | 0.27 | 0.27 | 0.27 | 0.27 | 0.27 | 0.50 | 0.50 | 0.50 | 0.50 | 0.50 |
| Fe₂O₃ | | | | | | | | | | | | | | | |
| TiO₂ | | | | | | 1.00 | | | | | | | | | |
| ZrO₂ | 0.11 | 0.25 | 0.25 | 0.15 | 0.15 | 0.15 | 0.15 | 0.20 | 0.20 | 0.40 | 0.10 | 0.10 | 0.10 | 0.10 | |
| CeO₂ | 0.16 | 0.15 | 0.15 | 0.15 | 0.15 | 0.15 | 0.02 | 0.15 | 0.15 | 0.15 | 0.15 | 0.15 | 0.15 | 0.15 | 0.15 |
| SnO₂ | | 0.14 | 0.14 | | | | | 0.14 | 0.14 | 0.14 | 0.14 | 0.14 | 0.14 | 0.14 | 0.10 |
| SO₃ | 0.03 | | | 0.03 | 0.03 | 0.03 | 0.03 | | | | | | | | |
| F | | | | | | | | | | | | | | | |
| Cl | | 0.20 | 0.20 | | | | | 0.55 | 0.55 | 0.55 | 0.55 | 0.55 | 0.55 | 0.55 | |

| Properties | V1 | V2 | V3 | V4 | V5 | V6 | V7 | V8 |
|---|---|---|---|---|---|---|---|---|
| CTE20-300 | 5.49 | 4.77 | 4.73 | 4.96 | 5 | 5.05 | 5.18 | 4.69 |
| [ppm/K] | | | | | | | | |
| Tg [° C.] | 560 | 586 | 620 | 608 | 581 | 592 | 614 | 601 |
| T2 (from | 1697 | 1691 | 1649 | 1620 | 1663 | 1619 | 1569 | 1703 |
| VFT) [° C.] | | | | | | | | |
| ρ [g/cm³] | 2.404 | 2.3955 | 2.4125 | 2.4191 | 2.4093 | 2.4222 | 2.4268 | 2.3954 |
| VA [° C.] | 1190 | 1201 | 1214 | 1190 | 1185 | 1165 | 1168 | 1234 |
| T3 [° C.] | 1394 | 1399 | 1393 | 1367 | 1376 | 1353 | 1334 | 1426 |
| VFT A | −2.129 | −2.178 | −2.664 | −2.646 | −2.278 | −2.105 | −2.752 | −2.567 |
| VFT B | 6417.5 | 6312.1 | 6760.5 | 6642.9 | 6353.3 | 5810.3 | 6430.3 | 7039.4 |
| VFT T0 | 142.7 | 179.9 | 199.0 | 190.5 | 178.0 | 203.2 | 216.1 | 162.1 |
| OEG [° C.] | 1185 | 1260 | 1260 | 1235 | 1215 | 1195 | 1275 | 1255 |
| lg (Liquidus | 4.03 | 3.67 | 3.71 | 3.71 | 3.85 | 3.75 | 3.32 | 3.87 |
| Viscosity) | | | | | | | | |
| [dPa*s] | | | | | | | | |

| Properties | V9 | V10 | V11 | V12 | V13 | V14 | V15 |
|---|---|---|---|---|---|---|---|
| CTE20-300 | 4.63 | 4.53 | 4.91 | 4.86 | 4.95 | 4.99 | 5.16 |
| [ppm/K] | | | | | | | |
| Tg [° C.] | 622 | 585 | 586 | 587 | 585 | 594 | 638 |
| T2 (from | 1664 | 1723 | 1705 | 1706 | 1704 | 1700 | 1841 |
| VFT) [° C.] | | | | | | | |
| ρ [g/cm³] | 2.4118 | 2.3724 | 2.3826 | 2.3829 | 2.3908 | 2.4004 | 2.404 |
| VA [° C.] | 1219 | 1224 | 1217 | 1217 | 1213 | 1210 | 1328 |
| T3 [° C.] | 1402 | 1426 | 1415 | 1415 | 1412 | 1408 | 1539 |
| VFT A | −2.603 | −2.230 | −2.307 | −2.257 | −2.221 | −2.162 | −2.580 |
| VFT B | 6754.0 | 6566.9 | 6624.7 | 6519.9 | 6444.4 | 6285.2 | 7732.7 |
| VFT T0 | 196.3 | 170.2 | 166.5 | 174.9 | 177.3 | 190.0 | 152.8 |
| OEG [° C.] | 1255 | 1265 | 1260 | 1240 | 1240 | 1245 | 1285 |
| lg (Liquidus | 3.78 | 3.77 | 3.75 | 3.86 | 3.84 | 3.80 | 4.25 |
| Viscosity) | | | | | | | |
| [dPa*s] | | | | | | | |

Comparative example V1 has an excessively high coefficient of thermal expansion, so that cooling results in higher stresses which, especially in the case of thin glass, can lead to buckling and/or cracking of the glass.

Comparative example V15 has an excessively high T2 temperature, so that the melt is excessively viscous at the temperatures used in industrial glass production and bubbles are removable only incompletely in the refining step, thus leading to low yield.

Comparative examples V2 to V14 exhibit an unfavorable position of OEG and VA relative to one another. Starting from the hot melt the viscosity range in which crystals may be formed thus begins sooner and the tendency for devitrification is altogether elevated. This is detrimental to producing such a glass with good yields.

The reported OEG, VA, T2 and CTE values for the working examples show that the glass provided according to the invention is very readily processible.

It is producible in good yield, especially also at low thicknesses, for example in the range from 0.3 to 0.7 mm. It does not have a tendency for crystallization. Stresses in the cooling lehr, which easily occur especially in the float process on account of the different cooling of the thin net-product glass and the thick border, can be very largely avoided.

The glass provided according to the invention is very amenable to chemical tempering.

Subjecting samples having the composition of the working examples to ion exchange under the following conditions:
ion exchange in an exchange bath having a composition of 20% by weight of KNO₃ and 80% by weight of NaNO3 at a temperature of the exchange bath of 420° C. and a duration of 7.5 hours and
a further ion exchange in an exchange bath having a composition of 100% by weight of KNO₃ and 0% by weight of NaNO3 at a temperature of the exchange bath of 390° C. and a duration of 3 hours,
results in the following properties as shown by way of example for exemplary glasses 6, 7, 8 and 9 in the following Table 3, which reports the values not only for CT (=center tension, i.e. tensile strength), CS30, CS50 and DoCL, but also for K—CS and K-DOL:

TABLE 3

| Exemplary | | | | |
|---|---|---|---|---|
| Glass | 6 | 7 | 8 | 9 |
| Glass | 0.479 | 0.477 | 0.472 | 0.509 |
| thickness | | | | |
| [mm] | | | | |
| CS30 | 137 | 133 | 139 | 154 |
| [MPa] | | | | |
| CS50 | 108 | 108 | 115 | 126 |
| [MPa] | | | | |
| DoCL [μm] | 111 | 108 | 109 | 117 |
| CT [MPa] | 133 | 135 | 142 | 144 |
| K-CS | 810 | 828 | 810 | 893 |
| [MPa] | | | | |
| K-DOL | 3.8 | 3.6 | 3.4 | 3.6 |
| [μm] | | | | |

The chemically tempered glass provided according to the invention thus has the following properties: CT>80 MPa, optionally CT>100 MPa, CS30>100 MPa, CS50>80 MPa and DoCL>0.17*t.

The glass provided according to the invention in the tempered state is thus very suitable for use as a cover for the recited applications; it combines the good product properties with very good production and processing properties.

While this invention has been described with respect to at least one embodiment, the present invention can be further modified within the spirit and scope of this disclosure. This application is therefore intended to cover any variations, uses, or adaptations of the invention using its general principles. Further, this application is intended to cover such departures from the present disclosure as come within known or customary practice in the art to which this invention pertains and which fall within the limits of the appended claims.

What is claimed is:

1. A chemically temperable or chemically tempered glass, comprising:
SiO₂, Al₂O₃, Li₂O and B₂O₃ as constituents, characterized in that the following applies for the constituents (in mol % based on oxide): 0.8<Li₂O/(Li₂O+K₂O+Na₂O)≤1 and 0.1<B₂O_{3≤8.5.}

2. The glass of claim 1, further comprising Na₂O and/or K₂O.

3. The glass of claim 1, characterized in that:
an upper devitrification temperature OEG is less than 10 K above a processing temperature VA;
a temperature at a viscosity of 10² dPas is at most 1800° C.; and
a coefficient of thermal expansion CTE20-300 is less than 5.4 ppm/K.

4. The glass of claim 1, wherein the glass comprises the following constituents (in mol % based on oxide):

| | |
|---|---|
| SiO₂ | 62-72; |
| Al₂O₃ | 7-14; |
| B₂O₃ | 0.1-8.5; |
| Li₂O | 5-12; |
| Na₂O | 0-2; and |
| K₂O | 0-2. |

5. The glass of claim 4, wherein the glass comprises the following constituents (in mol % based on oxide):

| | |
|---|---|
| SiO₂ | 65-70; |
| Al₂O₃ | 8-12; |
| B₂O₃ | 4-7; |
| Li₂O | 7-10; |
| Na₂O | 0-1; and |
| K₂O | 0-1. |

6. The glass of claim 1, wherein the glass further comprises the following constituents (in mol % based on oxide):

| | |
|---|---|
| MgO | 0-5; |
| CaO | 0-8; |
| SrO | 0-5; |
| BaO | 0-2; |
| ZnO | 0-5; |
| P₂O₅ | 0-5; and |
| ZrO₂ | 0-5. |

7. The glass of claim 6, wherein the glass comprises the following constituents (in mol % based on oxide):

| | |
|---|---|
| MgO | 0.5-3; |
| CaO | 1-6; |
| SrO | 0-1; |
| BaO | 0-2; |
| ZnO | 0-1; |
| P₂O₅ | 0.5-2; and |
| ZrO₂ | 0-3. |

8. The glass of claim 6, characterized in that the following applies for the constituents (in mol % based on oxide):
0.9<(Al₂O₃+B₂O₃+ZrO₂)/(R₂O+RO)<1.7; and/or
0.5<Al₂O₃/(R₂O+RO)<1.1; wherein R₂O=Li₂O+K₂O+Na₂O and RO=MgO+CaO+SrO+BaO+ZnO.

9. The glass of claim 8, wherein 1<(Al₂O₃+B₂O₃+ZrO₂)/(R₂O+RO)<1.6 and/or 0.6<Al₂O₃/(R₂O+RO)<0.9.

10. The glass of claim 1, wherein the glass contains 0 to 1 mol % of SnO₂ and/or 0 to 1 mol % of CeO₂, and/or 0 to 1 mol % of Cl.

11. The glass of claim 10, wherein the glass contains 0.1 to 0.5 mol % of SnO₂.

12. The glass of claim 10, wherein a sum of CeO₂+SnO₂+Cl is at most 2 mol %.

13. The glass of claim 1, wherein the glass is substantially free from coloring components.

14. The glass of claim 1, wherein the glass contains at least 0.1 mol % and at most 5 mol % of at least one coloring component.

15. A process for producing a tempered glass, the glass comprising SiO₂, Al₂O₃, Li₂O and B₂O₃ as constituents, wherein the following applies for the constituents (in mol % based on oxide): 0.8<Li₂O/(Li₂O+K₂O+Na₂O)≤1 and 0.1<B₂O_{3≤8.5}, the method comprising:
producing the glass by a melting process, a refining of a glass melt produced during the melting process, and a subsequent hot forming; and
performing at least one ion exchange in an exchange bath having a composition of 100% by weight to 0% by weight of KNO₃ and 0% by weight to 100% by weight of NaNO3 and 0% by weight to 5% by weight of LiNO₃ at a temperature of the exchange bath between 370° C. and 500° C. and a duration between 1 hour and 50 hours.

16. The process of claim 15, wherein the hot forming is carried out by a drawing process comprising a float process or a down-draw process.

17. A cover, comprising:
a tempered glass having a thickness of 0.3 mm to 1 mm, the glass comprising SiO₂, Al₂O₃, Li₂O and B₂O₃ as constituents, characterized in that the following applies for the constituents (in mol % based on oxide): 0.8<Li₂O/(Li₂O+K₂O+Na₂O)≤1 and 0.1<B₂O_{3≤8.5.}

18. The cover of claim 17, wherein the glass further comprises Na₂O and/or K₂O.

19. The cover of claim 17, characterized in that:
an upper devitrification temperature OEG of the glass is less than 10 K above a processing temperature VA of the glass;
a temperature at a viscosity of 10² dPas of the glass is at most 1800° C.; and
a coefficient of thermal expansion CTE20-300 of the glass is less than 5.4 ppm/K.

20. The cover of claim 17, wherein the glass comprises the following constituents (in mol % based on oxide):

| | |
|---|---|
| SiO₂ | 62-72; |
| Al₂O₃ | 7-14; |
| B₂O₃ | 0.1-8.5; |
| Li₂O | 5-12; |
| Na₂O | 0-2; and |
| K₂O | 0-2. |
